(19) United States
(12) Patent Application Publication
(10) Pub. No.: US 2010/0193013 A1
(43) Pub. Date: Aug. 5, 2010

(54) SOLAR POWER PLANT

(75) Inventor: Jong Hyun Kong, Masan-si (KR)

Correspondence Address: MITCHELL P. BROOK;LUCE, FORWARD, HAMILTON & SCRIPPS LLP, 600 West Broadway, Suite 2600, SAN DIEGO, CA, 92101, US

(73) Assignee: Urban Environment Engineering Co., Ltd., Gwangju (KR)

(21) Appl. No.: 12/678,719

(22) PCT Filed: Aug. 29, 2008
(86) PCT No.: PCT/KR08/05102

§ 371 Date: Mar. 17, 2010

(30) Foreign Application Priority Data
Sep. 18, 2007 (KR) 10-2007-0094941

(51) Int. Cl. H01L 31/048

(52) U.S. Cl. 136/251

(57) ABSTRACT

A solar power plant is provided. The solar power plant includes a plurality of first support members positioned in the front end of the solar power plant, main frames hinged to the respective first support members, a plurality of second support members positioned in the rear ends of the main frames, a plurality of sub frames rotatably installed on the main frames and arranged in parallel with one another, photovoltaic modules installed on the respective sub frames, and rotating means simultaneously rotating the sub frames with respect to the main frames by a predetermined angle in forward and reverse directions.

### TECHNICAL FIELD

The present invention relates to a solar power plant having a solar tracking apparatus, and more particularly to a solar power plant having a solar tracking apparatus which can increase the collection efficiency of photovoltaic modules.

### BACKGROUND ART

Solar power generation technology is different from solar heat generation technology in which radiant heat energy transmitted from the sun is utilized. The solar power generation technology utilizing limitless clean energy has several advantages, including no necessity of additional energy or driving source, simple construction whether it is a small system or a large system, and no strain on the environmental limitation.

On the other hand, the solar power generation technology is disadvantageous in that the amount of energy generated may vary by the sunshine duration. In addition, a large number of photovoltaic modules are required to yield a relatively large amount of power, and the power generated based on the solar power generation technology is expensive compared to commercial power. Further, DC power is first obtained. The photovoltaic modules are classified into a tracking type in which the sun is tracked in a power-driven manner or by device manipulation to allow direct rays of sunlight to enter the front surface of the photovoltaic modules in a vertical direction all the time in order to maximize the generation efficiency; a semi-fixed type in which the photovoltaic modules are vertically adjustable in positions by season or month; and a fixed type in which positions of the photovoltaic modules are fixed regardless of the altitude with respect to the sun.

The solar tracking apparatus moves a solar collector or lens in order to increase collection efficiency while tracking the sun on the move. Solar tracking methods are largely classified into programmed tracking and sensor-based tracking. In the former tracking method, the movement of the sun based on the rotation of the earth on its axis and the revolution of the earth round the sun is preprogrammed and photovoltaic modules are rotated. In the latter tracking method, the movement of the sunlight is sensed and directions of photovoltaic modules are controlled. Along with the technological advance of the related art in various applications, a variety of improvements are being made. The solar tracking apparatus employs various techniques including sun position detection, use of tracking members, tracking driving system, and so on.

Korea Patent No. 044021 discloses a solar tracking method using a solar tracking apparatus. In the disclosed solar tracking method, the solar tracking apparatus is constructed such that when the normal azimuth of a photovoltaic module lags behind the sun's azimuth by a first angle, the normal azimuth of the photovoltaic module photovoltaic module may precede the sun's azimuth by a second angle.

Korea Patent No. 0483291 discloses a sun position tracking method for a solar heat system. Korea Patent No. 0369897 discloses a combined solar tracking controller for a focusing type solar heat collector.

As described above, the conventional solar tracking apparatus has several disadvantages in view of its relative complex structure, inaccurate positioning, and so on. In particular, it is quite difficult to simultaneously drive various photovoltaic modules along the sun.

### DISCLOSURE OF INVENTION

### Technical Problem

To solve the above problems, it is an object of the present invention to provide a solar power plant having a solar tracking apparatus, which can increase the focusing efficiency of photovoltaic modules, by simultaneously tracking the sun using the photovoltaic modules westwards and facilitating the altitude adjustment northwards.

It is another object of the present invention to provide a solar power plant having a solar tracking apparatus, which can reduce leeway resistance by separating photovoltaic modules and can simultaneously track photovoltaic modules along the sun westwards.

It is still another object of the present invention to provide a solar power plant having a solar tracking apparatus, which can adjust the tilt direction of a track photovoltaic module northwards.

### Technical Solution

According to an aspect of the present invention, there is provided a solar power plant including a plurality of first support members positioned in the front end of the solar power plant, main frames hinged to the respective first support members, a plurality of second support members positioned in the rear ends of the main frames, a plurality of sub frames rotatably installed on the main frames and arranged in parallel with one another, photovoltaic modules installed on the respective sub frames, and rotating means simultaneously rotating the sub frames with respect to the main frames by a predetermined angle in forward and reverse directions.

In the present invention, the solar power plant may further comprise elevating means installed on at least one of the plurality of second support members, for moving the main frames up and down. The elevating means may include first links rotatably supported on the second support members and having both ends protruding from the second support members, second links each having both ends hinged to one end of each of the first links and the rear end of each of the main frames, and an each installed at the second support members and hinged to the other ends of the second links to rotate the first links.

The rotating means comprises rotatable links capable of simultaneously rotating sub frames installed on the main frames with respect to the main frames, the rotatable links installed on the rotation shafts of the respective sub frames or the sub frames; connection links connecting ends of the respective rotatable links; and an actuator installed on the first support member to be connected to one of the sub frames or the connection links for rotating the rotation shafts in forward and reverse directions or reciprocating the connection links back and forth.

Alternatively, according to another aspect of the present invention, there is provided a solar power plant comprising: a plurality of first support members positioned at front ends; a plurality of second support members main frames hinged to rear ends of the main frames; a plurality of sub frames rotatably installed on the main frames and arranged to be parallel with one another; photovoltaic modules installed on the respective sub frames; and rotating means rotating the rotation shafts or one of the sub frames, and including extension brackets extending downwardly from the bottom surface of the respective sub frames, linking brackets interconnecting the extension brackets, and an actuator installed on the main frames or the sub frames.

Here, the solar power plant may further comprise elevating means installed between the second members and the main frames and elevating the main frames up and down.

### BRIEF DESCRIPTION OF THE DRAWINGS

FIG. 1 is a plan view of a solar power plant according to an embodiment of the present invention;

FIG. 2 is a perspective view of the solar power plant according to an embodiment of the present invention;

FIG. 3 is a perspective view of another example of the solar power plant of the present invention shown in FIG. 2;

FIG. 4 is a side view of the solar power plant shown in FIG. 1;

FIG. 5 is a cross-sectional view of a solar power plant shown in FIG. 3;

FIG. 6 is an exploded perspective view of rotating means of the solar power plant;

FIG. 7 is a plan view of a solar power plant according to another embodiment of the present invention;

FIG. 8 is a perspective view of the solar power plant shown in FIG. 7;

FIG. 9 is a side view of the solar power plant shown in FIG. 7;

FIG. 10 is a side view of rotating means for rotating a photovoltaic module of the solar power plant;

FIG. 11 is a perspective view of a solar power plant according to still another embodiment of the present invention;

FIG. 12 is a side view illustrating the operation state of the solar power plant shown in FIG. 11;

FIG. 13 is a perspective view of a solar power plant according to a further embodiment of the present invention; and

FIG. 14 is a side view illustrating the operation state of the solar power plant in FIG. 13.

### BEST MODE FOR CARRYING OUT THE INVENTION

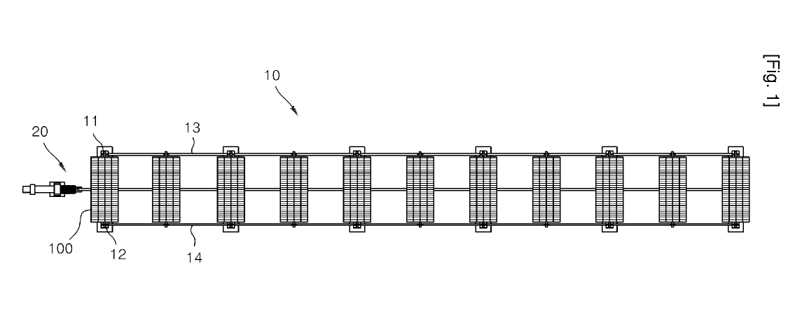

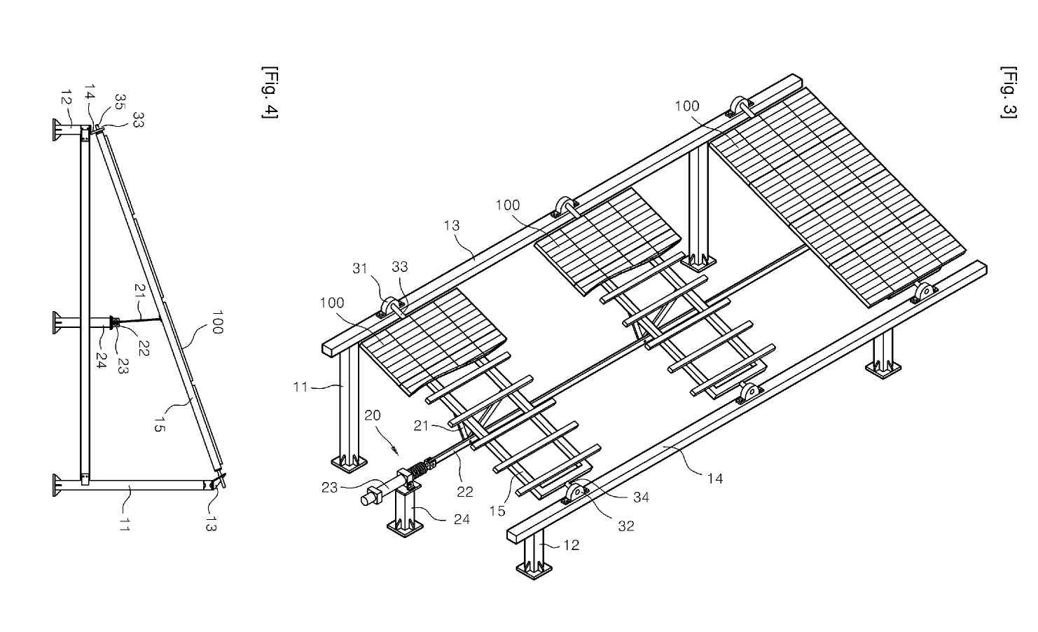

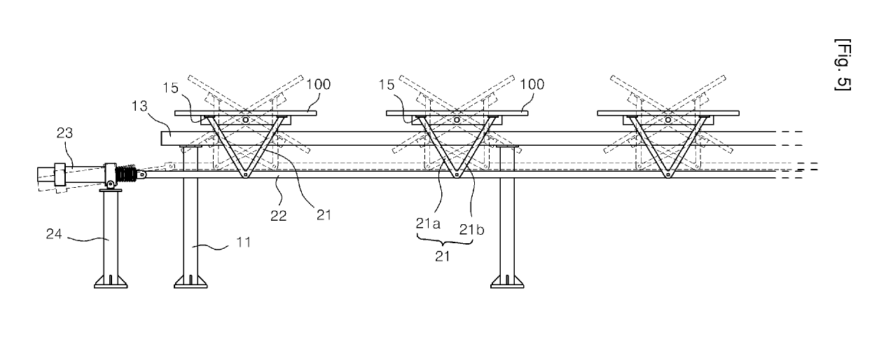

The solar power plant according to the present invention tracks the diurnal motion of the sun from the east to the west and adjusts its altitude with respect to the sun, thereby generating the electricity. The solar power plant according to an embodiment of the present invention is shown in FIGS. 1 through 6.

Referring to FIGS. 1 through 6, the solar power plant 10 includes first and second support members 11 and 12 installed on the ground, slant land, or a building and having the same or different heights, main frames 13 and 14 hinged to the respective first and second support members 11 and 12, sub frames 15 installed in a direction parallel to the main frames 13 and 14, for example, northwards, photovoltaic modules 100 installed on the respective sub frames 15, and rotating means 20 simultaneously rotating the sub frames 15 having the photovoltaic modules 100.

When installing the sub frames 15 for the main frames 13 and 14, first and second pillow blocks 31 and 32 are installed on the main frames 13 and 14 corresponding to the first and second support members 11 and 12, respectively, and first and second rotation shafts 33 and 34 are rotatably installed on the first and second pillow blocks 31 and 32 installed on opposite sides on the sub frames 15 northwards, respectively. One or a plurality of photovoltaic modules 100 are installed on the sub frames 15. The main frames 13 and 14 are supported by the first and second support members 11 and 12, respectively, and arranged in parallel with each other. However, the arrangement of the main frames 13 and 14 is not limited to the illustrated example but rectangular arrangement may be possible. In other words, heights of the first and second support members 13 and 14 may vary according to their positions installed, that is, the latitudes. In the celestial equator region, for example, the sub frames 15 for installing the respective photovoltaic modules 100 having substantially the same height are preferably maintained at a horizontal position. A height difference between the first and second support members 11 and 12 is preferably made to be larger to make a tilt angle of the sub frames 15, i.e., the photovoltaic modules 100 installed on the sub frames 15 as the positions shift from the celestial equator region to the southern pole or the northern pole.

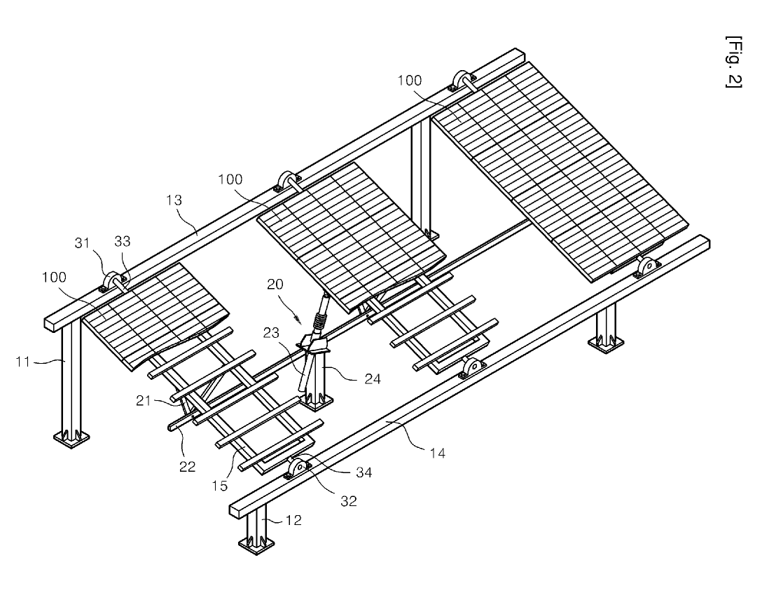

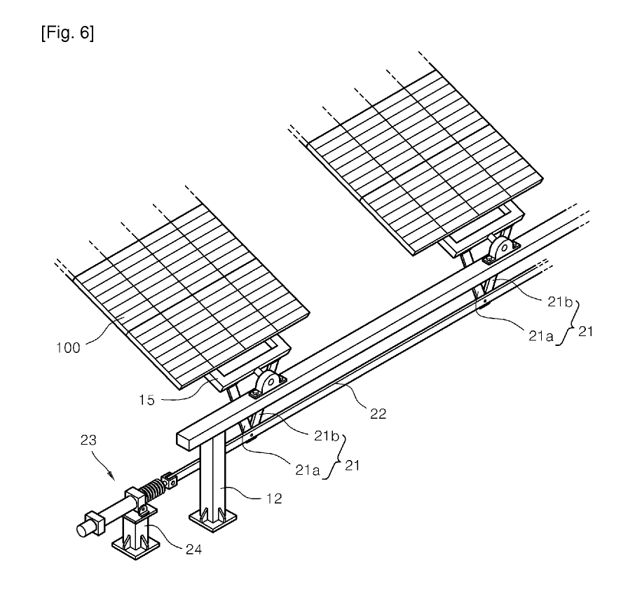

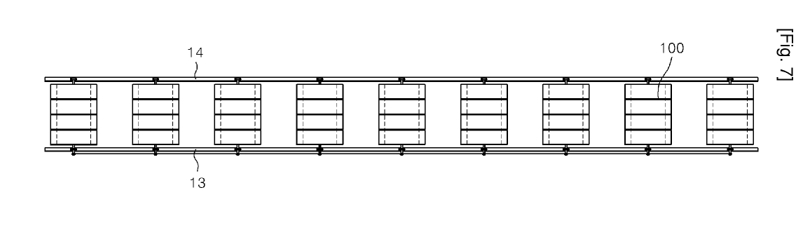

The rotating means 20 performs tracking by simultaneously rotating the respective sub frames 15 with respect to the main frames 13 and 14 along the sun westwards. As shown in FIGS. 2 through 2 through 5, the rotating means 20 includes linking brackets 21 extending downwardly from the bottom surface of each of the respective sub frames 15, and connection links 22 to which the linking brackets 21 are rotatably hinged. The linking brackets 21 are installed on the bottom surface of each of the respective sub frames 15 in order to reinforce structural rigidity. The linking brackets 21 may have first and second members 21a and 21b whose ends are hinged to one of hinge shafts thereof which are positioned below the sub frames 15. As shown in FIG. 6, the linking brackets 21 including the first and second members 21a and 21b are preferably installed at end portions of the sub frames 15 without the photovoltaic modules 100. In such a case, even if the rotation angles of the sub frames 15 are increased, interference between the sub frames 15 or the photovoltaic modules 100 and the linking brackets 21 may be avoided.

In addition, an actuator 23 for reciprocating the connection link 22 back and forth is installed at an end of the connection link 22. The actuator 23 may be comprised of, but not limited to, a screw jack having a structure capable of transmitting the driving force of a motor to a screw by means of a decelerator, as shown in FIG. 2.

As shown in FIG. 6, the actuator 23 may be rotatably installed at either side of the first and second support members 11 and 12 or may be rotatably installed at a separate support member 24.

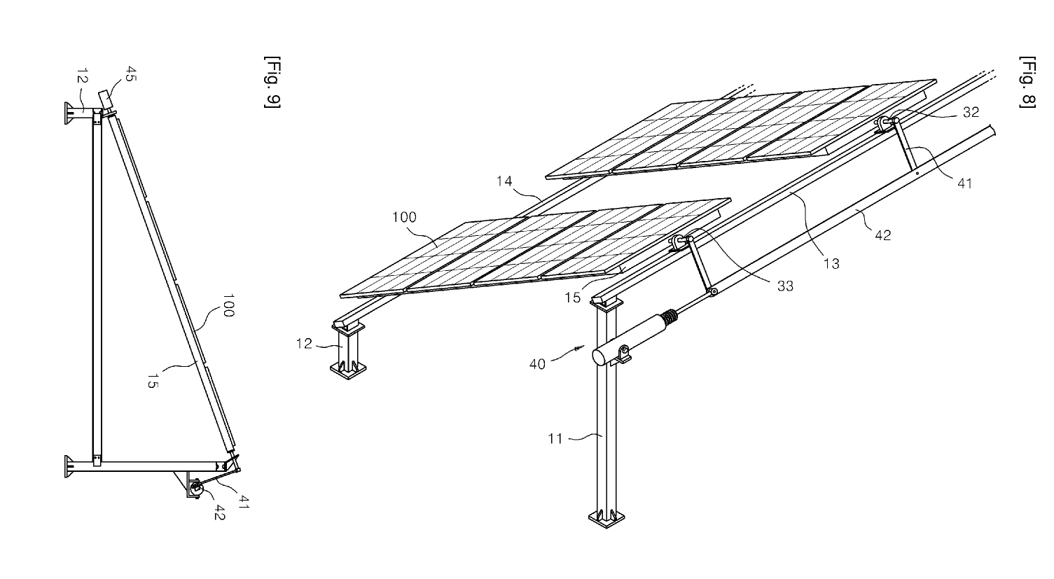

FIG. 7 is a plan view of a solar power plant according to another embodiment of the present invention, and FIG. 8 is a perspective view of the solar power plant shown in FIG. 7.

FIGS. 7 through 9 illustrate other examples of rotating means according to the present invention, in which the same reference numerals denote the same components. As illustrated, rotating means 40 includes rotatable links 41 installed at first rotation shafts 33 of the respective sub frames 15 rotatably installed on the main frames 13 and 14, and drive links 42 hinged to ends of the rotatable links 41. In addition, the rotating means 40 includes an actuator 43 as angle adjusting means for adjusting angles of the respective sub frames 15 connected to the rotatable links 41 and the drive links 42 by rotating one or both of the respective sub frames 15 by reciprocating the drive links 42 back and forth (see FIG. 8). The actuator 43 is rotatably installed at the first support member 11 or the main frames 13 and 14 and may be comprised of a jack screw having the aforementioned structure. As shown in FIG. 9, the actuator 43 may be a motor 45 rotatably installed on the first support member 11 for rotating the first rotation shaft 33 of one of the respective sub frames 15 in forward and reverse directions.

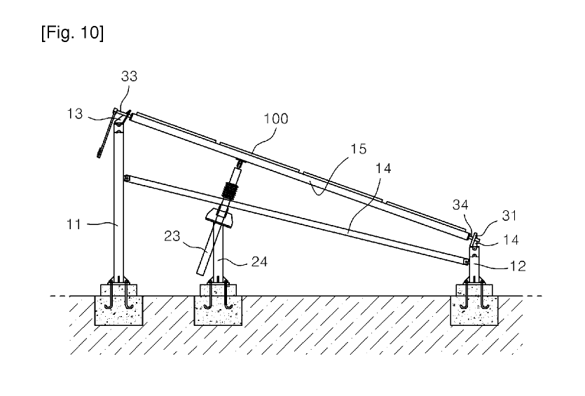

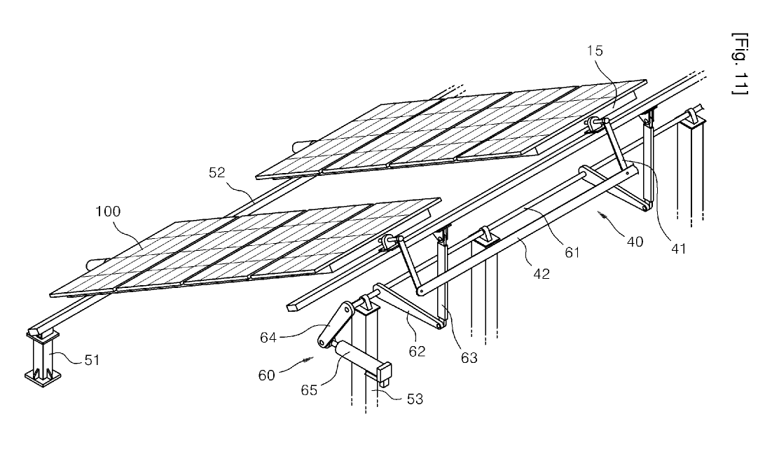

Alternatively, as shown in FIG. 10, the actuator 43 may be a cylinder or a jack screw installed on the first support member 11 and reciprocating the drive links 42 back and forth.

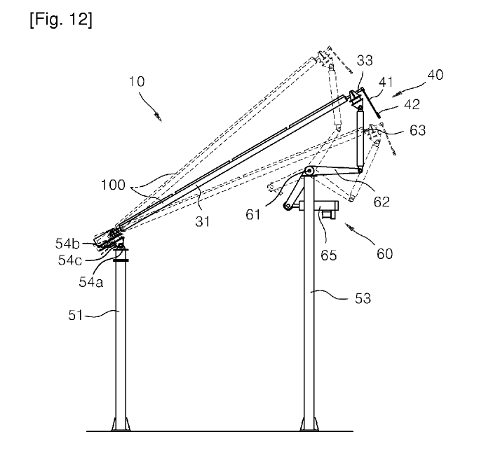

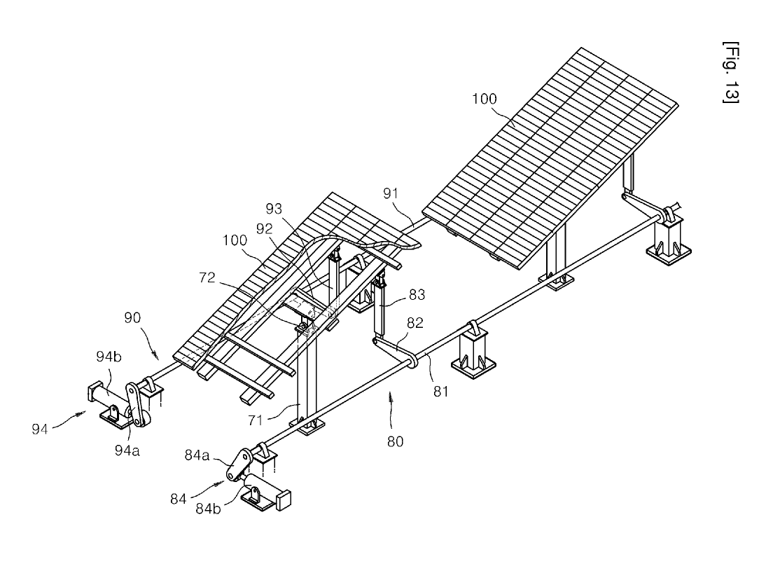

FIGS. 11 and 12 illustrate a solar power plant according to still another embodiment of the present invention.

Referring to FIGS. 11 and 12, the solar power plant 50 includes first support members 51 installed on the ground, slant land, or a building, main frames 52 hinged to the first support members 51, second support members 53 installed on rear ends of the main frames 52, and elevating means installed on the second members 53 and elevating the main frames 52 up and down about the first support members 51. The main frames 52 may be formed in a matrix type such that sub frames to be described later are arranged in parallel with one another.

Hinge coupling between the first support members 51 and the main frames 52 may be made by installing first and second brackets 54a and 54b at corresponding portions of the first support members 51 and the main frames 52 and coupling the same by means of hinge pins 54c.

The elevating means 60 includes drive shafts 61 supported by the second support members 53, first links 62 connected to the drive shafts 61, and second links 63 connecting ends of the respective first links 62 with rear ends of the main frames. Thirds links 64 are installed at the drive shafts 61, and the third links 64 are rotated by a rotatable actuator 65 installed on the second support members 53 by a predetermined angle. Here, the rotatable actuator 65 may be comprised of a jack screw having a lead screw reciprocating back and forth by being rotated in forward and reverse directions by means of a cylinder or a motor.

The elevating means is not limited to the illustrated example and any structure can be used as long as it can rotate the main frames 52 about the first support members 51.

As described above, the solar power plant 50 includes a plurality of sub frames 15 rotatably installed on the main frames 52 and arranged to be parallel with one another, and photovoltaic modules 100 installed on the respective sub frames 15, and rotating means 20 for rotating the sub frames 15 with respect to the main frames 52 by a predetermined angle in forward and reverse directions. The rotating means 20 are substantially the same as in the previous embodiments and an explanation thereof will not be given. As a matter of course, there is no interference while rotating the sub frames 15.

Meanwhile, damping means for preventing the main frames 52 from abruptly elevating or lowering with respect to the second support members 53 may be separately provided in the second support members 53 having the elevating means 60. For example, the damping means is preferably a shock absorber.

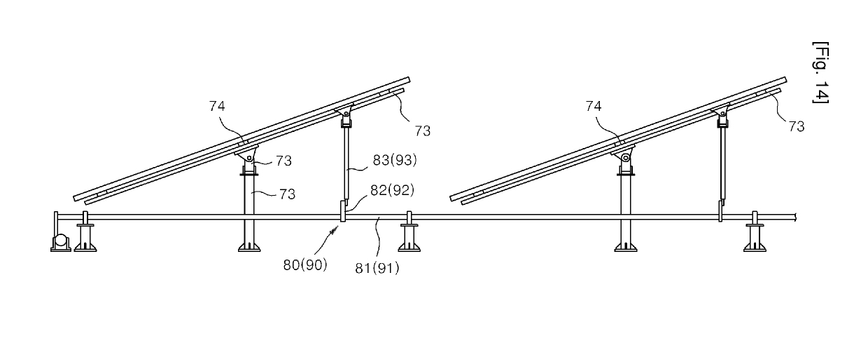

FIG. 13 is a perspective view of a solar power plant according to a further embodiment of the present invention.

Referring to FIG. 13, the solar power plant includes main frames 73 installed by hinge portions 72 so as to be rotated by main support members 71 by a predetermined angle, sub frames 74 installed on the main frames 73, photovoltaic modules 100 installed on the sub frames 74, and first and second angle adjusting means 80 and 90 installed at opposite sides of the main support members 71 and rotating the main frames 73 at a predetermined angle and adjusting the heights of the main frames 73.

The hinge portions 72 may be universal joints or ball joints capable of adjusting rotation of the main frames 73 at a predetermined angle.

The first angle adjusting means 80 may include a first driver 84 having a first rotation shaft 81 rotatably installed at either side of the main support member 71, a first rotatable link 82 installed at the first rotation shaft 81, and a second rotatable link 83 connecting the first rotatable link 82 and the main frame 83. Here, the second rotatable link 83 and the main frame 73 are coupled to each other by hinge coupling. As described above, the hinge coupling can be made by means of universal joints or ball joints. In addition, the first driver 84 may be provided at ends of the first rotation shafts 81.

The first driver 84 may include a jack screw 84b connected to the first rotation shaft 81 by a link 84a.

The second angle adjusting means 90 may have substantially the same structure as the first angle adjusting means. The second angle adjusting means 90 may include second driver 94 having a second rotation shaft 91 rotatably installed at the other side of the main support member 71, a third rotatable link 92 installed at the second rotation shaft 91, and a fourth rotatable link 93 connecting the third rotatable link 92 and the main frame 73, the second driver 94 provided at ends of the second rotation shaft 91 for rotating the second rotation shaft by a predetermined angle. Here, each of the second driver 94 may include a jack screw 94b connected to the second rotation shaft 91 by a link 94a.

The first and second angle adjusting means are not limited to the illustrated examples, and any structures can be used as long as they are capable of independently elevating the main frames 73 supported by the main support member 71.

The aforementioned solar power plant operates as follows. At sunrise, the solar power plant 10 operates such that the elevating means 60 is driven to rotate the photovoltaic modules 100 installed on the sub frames 15 so as to be aligned with the sun. Here, if the photovoltaic modules 100 installed on the sub frames 15 are aligned with the sun, they are maximally exposed to the sun, suggesting that a large amount of sunlight is irradiated.

In such a state, the sun's azimuth varies as the sun follows the ecliptic over time. The azimuth of a photovoltaic module and the sun's azimuth are sensed by a sensor (not shown), and the actuator (23 or 40) is driven based on the information obtained by the sensor, thereby rotating the respective sub frames 15 by a predetermined angle.

Accordingly, the photovoltaic modules 100 can track the sun all day, thereby maximizing generation efficiency.

Meanwhile, due to the seasonal change of the altitude, heights of the elevating means 60 installed on the main frames 51 can be adjusted in a south-north direction, that is, in a direction in which the sun follows the ecliptic.

In other words, the rotatable actuator 65 is driven to rotate the first links 62, thereby rotating the second links 63 to rotate the second links 63 connecting the same with rear ends of the main frames 52, and adjusting the heights of the main frames 52 by elevating rear ends of the main frames 52.

The solar tracking system can maximize the efficiency of the photovoltaic modules 100 according to the present invention while simplifying the structures of the photovoltaic modules 100, compared to the conventional solar tracking system using the sun's azimuth altitude.

In particular, as shown in FIGS. 1 through 5, since the sub frames 15 having the photovoltaic modules 100 rotatably installed thereon at a predetermined angle with respect to the main frames 13 and 14 can rotate the photovoltaic modules 100 by the predetermined angle using an actuator, i.e., the screw jack 23, the solar tracking performance can be improved, and generation efficiency can also be enhanced compared to the fixed type photovoltaic modules.

Referring to FIGS. 13 and 14, the main frames 73 rotatably installed by the main support members 71 and the hinge portions 72 selectively rotate the first and second drivers 84 and 94 of the first and second angle adjusting means 80 and 90, thereby rotating the first or second rotation shafts 81 or 91. In such a manner, the main frames 73 connected by the first and second rotation shafts 81 and 91 and the first and second rotatable links 82 and 83 or the third and fourth rotatable links 92 and 93, specifically, the photovoltaic modules, can be adjusted in view of angles and altitudes.

As described above, the solar power plant according to the present invention can increase the collection efficiency by rotating the main frames in a south-north direction and tracking the sun along the course of the ecliptic, i.e., westwards, while maximizing generation efficiency by manually or automatically adjusting the angles of the photovoltaic modules depending on their altitudes over time of month or season. In addition, since the solar tracking according to the present invention is simple, a high degree of design freedom can be achieved. Further, the simplified configuration can reduce the manufacturing cost associated with the solar power plant according to the present invention.

Since the solar power plant according to the present invention can adjust the altitude by elevating sub frames in the south-north directions and can track the sun by rotating the sub frames in the east-west directions, it can increase the collection efficiency of sunlight. In addition, angles of photovoltaic modules can be adjusted according to the sun's altitude by the season or month of the year, thereby maximizing generation efficiency.

While the present invention has been particularly shown and described with reference to exemplary embodiments thereof, it will be understood by those of ordinary skill in the art that various changes in form and details may be made therein without departing from the spirit and scope of the present invention as defined by the following claims.

It is therefore desired that the present embodiments be considered in all respects as illustrative and not restrictive, reference being made to the appended claims rather than the foregoing description to indicate the scope of the invention.

### INDUSTRIAL APPLICABILITY

Since the solar power plant according to the present invention can be designed and constructed on any installation site, e.g., the slant land, the mountainous area, or a building, without space restriction, it can be widely utilized to a variety of photovoltaic power generation fields.

1. A solar power plant comprising:
a plurality of first support members positioned in the front end of the solar power plant;
main frames hinged to the respective first support members;
a plurality of second support members positioned in the rear ends of the main frames;
a plurality of sub frames rotatably installed on the main frames and arranged in parallel with one another;
photovoltaic modules installed on the respective sub frames; and
rotating means simultaneously rotating the sub frames with respect to the main frames by a predetermined angle in forward and reverse directions.

2. The solar power plant of claim 1, further comprising elevating means installed on at least one of the plurality of second support members, for moving the main frames up and down.

3. The solar power plant of claim 2, wherein the elevating means includes first links rotatably supported on the second support members and having both ends protruding from the second support members, second links each having both ends hinged to one end of each of the first links and the rear end of each of the main frames, and an each installed at the second support members and hinged to the other ends of the second links to rotate the first links.

4. The solar power plant of claim 1, wherein the rotating means comprises:
rotatable links capable of simultaneously rotating sub frames installed on the main frames with respect to the main frames, the rotatable links installed on the rotation shafts of the respective sub frames or the sub frames;
connection links connecting ends of the respective rotatable links; and
an actuator installed on the first support member to be connected to one of the sub frames or the connection links for rotating the rotation shafts in forward and reverse directions or reciprocating the connection links back and forth.

5. A solar power plant comprising:
a plurality of first support members positioned at the front end of the solar power plant;
main frames hinged to the first support members;
a plurality of second support members positioned at rear ends of the main frames;
photovoltaic modules rotatably installed on the main frame and installed on the respective sub frames parallel with one another;
* extension brackets extending downwardly from the bottom surface of the respective sub frames;
linking brackets interconnecting the extension brackets; and
rotating means comprises:
an actuator installed on the main frames or the sub frames and rotating the rotation shafts or one of the sub frames.

6. The solar power plant of claim 5, further comprising elevating means installed between the second members and the main frames and elevating the main frames up and down.

7. A solar power plant comprising:
a main frame;
a plurality of support members supporting the main frame from front and rear ends thereof;
a plurality of sub frames rotatably installed on the main frame and arranged in parallel with one another; and
photovoltaic modules installed on the respective sub frames; and
rotating means simultaneously rotating the sub frames with respect to the main frame by a predetermined angle in forward and reverse directions.

8. A solar power plant comprising:
main frames installed by hinge portions so as to be rotated by main support members at a predetermined angle;
sub frames installed on the main frames;
photovoltaic modules installed on the sub frames; and
first and second angle adjusting means installed at opposite sides of the main support members and rotating the main frames at a predetermined angle and adjusting the heights of the main frames. *

9. The solar power plant of claim 8, wherein the first angle adjusting means includes a first driver having a first rotation shaft rotatably installed at one side of the main support member, a first rotatable link installed at the first rotation shaft, and a second rotatable link connecting the first rotatable link and the main frame, the first driver provided at one end of the first rotation shaft for rotating the first rotation shaft by a predetermined angle; and the second angle adjusting means include a second driver having a second rotation shaft rotatably installed at the other side of the main support member, a third rotatable link installed at the second rotation shaft, and a fourth rotatable link connecting the third rotatable link and the main frame, the second driver provided at the other end of the second rotation shaft for rotating the second rotation shaft by a predetermined angle.
